(19) United States
(12) Patent Application Publication
(10) Pub. No.: US 2002/0173078 A1
(43) Pub. Date: Nov. 21, 2002

(54) Method and apparatus for manufacturing semiconductor device

(76) Inventors: Yumiko Kawano, Iwakubo-cho (JP); Hideaki Yamasaki, Yamanashi (JP); Gishi Chung, Yamanashi (JP)

Correspondence Address: BAKER & McKENZIE, 12th Floor, 101 West Broadway, San Dieg, CA, 92101, US

(21) Appl. No.: 10/052,306

(22) Filed: Jan. 18, 2002

Related U.S. Application Data
(63) Continuation of application No. PCT/JP00/04889, filed on Jul. 21, 2000.

(30) Foreign Application Priority Data
Jul. 26, 1999 (JP) H11-210149

(51) Int. Cl. H01L 21/44

(52) U.S. Cl. 438/115

(57) ABSTRACT

As a preparation process, a gas supply source 10A supplies WF₆ gas for restricting formation of nuclei for growing a metal film onto a surface of a process target semiconductor wafer W for a predetermined period of time. After the preparation process is performed, the gas supply source 10A and a gas supply source 10B respectively supply WF₆ gas and NH₃ gas onto the surface of the semiconductor wafer W to which the preparation process has been applied, for a predetermined period of time. Thus, a tungsten nitride film which is a metal compound film whose surface has bumps is formed on the semiconductor wafer W. A controller 51 controls operations of the gas supply sources 10A and 10B, and the like in accordance with a program or the like previously provided.

### TECHNICAL FIELD

The present invention relates to a method and an apparatus for manufacturing a semiconductor device, and particularly relates to a method and an apparatus for manufacturing a semiconductor device including a capacitor having large capacitance.

### BACKGROUND ART

As semiconductor devices become more miniaturized, smaller-sized capacitors (condensers) having larger capacitance are requested. In accordance with this request, Ta₂O₅ are replacing SiO₂ as the material for capacitance insulation films. Also, the structure of capacitors are changing from MIS (Metal film/Insulation film/Silicon) to MIM (Metal film/Insulation film/Metal film).

The followings are requested when manufacturing a capacitor having the MIM structure. First, a metal film to be used as a lower electrode has an excellent coverage. Second, the lower electrode is not easily oxidized or does not easily flake off during a capacitance insulation film forming step or a crystallization step carried out in an oxidizing atmosphere after formation of the lower electrode.

Tungsten nitride is known as a material of a lower electrode that satisfies those requests. Tungsten nitride is not as easy to be oxidized as tungsten and titanium nitride.

The following five methods are known as methods of forming a lower electrode made of tungsten nitride.

(1) A thermal CVD method using WF₆ gas and NH₃ gas

(2) A plasma CVD method using WF₆ gas and NH₃ gas (Unexamined Japanese Patent Application KOKAI Publication No. S64-501)

(3) A plasma CVD method using WF₆ gas, N₂ gas, and H₂ gas (Unexamined Japanese Patent Application KOKAI Publication No. S64-501)

(4) A plasma CVE method using WF₆ gas and NF₃ gas (Suzuki et. al “Advanced Mettalization and Interconnect Systems for ULSI Application in 1997” Mater. Res. Soc., 1998, 49)

(5) A thermal CVD method using organic tungsten source (Sun et. al., Proc. of 13th VMIC, 151, 1996)

When comparing the above methods (2) to (5) with the method (1), those methods (2) to (5) result in forming a tungsten nitride film having a less favorable coverage, and spending more costs.

A tungsten nitride film formed by the method (1) has a plane surface, thus, the front area of the lower electrode is small. Therefore, the method (1) cannot realize enlargement of capacitance of capacitors.

It is an object of the present invention to provide a semiconductor device manufacturing method and apparatus capable of forming a capacitor having large capacitance. It is another object of the present invention to provide a semiconductor device manufacturing method and apparatus capable of forming a metal film having a bumpy shape.

### DISCLOSURE OF INVENTION

To accomplish the above objects, a method of manufacturing a semiconductor wafer according to a first aspect of the present invention comprises:

a preparation process step of supplying a substance for restricting formation of nuclei for growing a metal film or a metal compound film onto a surface of a process target substrate; and

a film forming step of forming a metal film or a metal compound film whose surface has bumps on the substrate by supplying a material of the metal film or the metal compound film onto the surface of the substrate after the preparation process step.

According to this invention, by applying a preparation process before forming a metal film or a metal compound film on a substrate (a base substrate for growth of a metal film or a metal compound film, and including an interlayer insulation film or the like), bumps can be formed on the surface of the metal film. And by using such a metal film as an electrode, a capacitor having large capacitance can be manufactured.

The preparation process step may comprise a step of supplying a substance for restricting adhesion of NH₃ onto the surface of the substrate. The film forming step may comprise a step of forming a tungsten nitride film whose surface has bumps on the substrate by supplying WF₆ and NH₃ onto the surface of the substrate.

The preparation process step may comprise a step of restricting adhesion of NH₃ onto the surface of the substrate by supplying a halogen element onto the surface of the substrate. The preparation process step may comprise a step of supplying ClF₃ or WF₆ onto the surface of the substrate as the halogen element.

The preparation process step may comprise a step of restricting adhesion of NH₃ onto the surface of the substrate by bonding groups made of C and H onto the surface of the substrate.

The preparation process step may comprise a step of coating and drying at least one of HMDS, alcohol, and ketone onto the surface of the substrate in order to bond groups made of C and H onto the surface of the substrate.

The preparation process step may comprise a step of exposing the surface of the substrate to vapor of at least one of HMDS, alcohol, and ketone, and drying the vapor in order to bond groups made of C and H onto the surface of the substrate.

The preparation process step may comprise a step of using C₂H₅OH as the alcohol.

The preparation process step may comprise a step of using CH₃COCH₃ as the ketone.

A method of manufacturing a semiconductor device according to a second aspect of the present invention comprises:

a preparation process step of supplying a halogen element onto a surface of a substrate; and

a film forming step of forming a metal film or a metal compound film whose surface has bumps on the substrate by supplying a material of the metal film or the metal compound film onto the surface of the substrate after the preparation process step.

A method of manufacturing a semiconductor device according to a third aspect of the present invention comprises:

a preparation process step of bonding groups made of C and H onto a surface of a substrate; and

a film forming step of forming a metal film or a metal compound film whose surface has bumps on the substrate by supplying a material of the metal film or the metal compound film onto the surface of the substrate after the preparation process step.

The film forming step may control a shape of the bumps on the metal film or the metal compound film formed in the film forming step by controlling a time in which a preparation process is performed.

In the methods of manufacturing a semiconductor device according to the first to third aspects; the preparation process step is a step of supplying the substance for restricting formation of nuclei onto the surface of the substrate that is substantially plane; and the film forming step is a step of forming a metal film or a metal compound film which has bumps on the substrate, for example.

In the methods of manufacturing a semiconductor device according to the first to third aspects; the preparation process step is a step of supplying the substance for restricting formation of nuclei onto the surface of the substrate that has predetermined roughness; and the film forming step is a step of forming on the substrate, a metal film or a metal compound film which has bumps that are rougher than the surface of the substrate, for example.

The methods of manufacturing a semiconductor device according to the first to third aspects may form capacitance by preparing a step of forming a conductive film which faces the metal film or the metal compound film via an insulation material.

An apparatus for manufacturing a semiconductor device according to a fourth aspect of the present invention comprises:

a first process room in which a preparation process is applied to a substrate;

a restriction substance supply source which supplies a restriction substance for restricting formation of nuclei for growing a metal film or a metal compound film to the first process room;

a second process room in which a film forming process for forming a metal film or a metal compound film whose surface has bumps is performed; and

a material gas supply source which supplies a material gas for forming the metal film or the metal compound film whose surface has bumps to the second process room.

The restriction substance supply source may supply onto a surface of the substrate which is arranged on a predetermined position in the first process room, a gas including a halogen element for restricting adhesion of NH₃ as the preparation process. The material gas supply source may form a tungsten nitride film on the substrate by supplying WF₆ gas and NH₃ gas onto the surface of the substrate to which the preparation process has been applied.

The restriction substance supply source may supply WF₆ or ClF₃ as the halogen element.

The restriction substance supply source may include gas guiding means for supplying the gas including a halogen element onto the substrate substantially uniformly.

The first process room and the second process room may be capable of keeping a pressure therein at a predetermined level, and may be connected to each other via a vacuum room which includes transportation means for transporting the substrate.

The first process room and the second process room may be a same process room.

The material gas supply source may supply WF₆ gas and NH₃ gas onto the substrate in the second process room via different paths respectively.

The restriction substance supply source may supply a substance including groups made of C and H as the restriction substance as the preparation process. The first process room may include coat and dry means for bonding groups made of C and H onto a surface of the substrate by coating and drying the restriction substance on the surface of the substrate. The first process room may include means for bonding groups made of C and H onto a surface of the substrate by flowing vapor of the restriction substance above the surface of the substrate.

The second process room forms a metal film or a metal compound film on the surface of the substrate on which formation of nuclei is restricted by the process performed in the first process room, for example. The surface has predetermined roughness and the metal film or the metal compound film has bumps which are rougher than the surface of the substrate.

Or, the second process room forms a metal film or a metal compound film which has bumps on a surface of the substrate on which formation of nuclei is restricted by the process performed in the first process room, for example. The surface is plane.

The apparatus for manufacturing a semiconductor device may further comprise: a device which forms an insulation material on the metal film or the metal compound film; and a device which forms a conductive material on the insulation material.

### BRIEF DESCRIPTION OF DRAWINGS

FIG. 1 is a diagram illustrating a structure of a thermal CVD (Chemical Vapor Deposition) film forming apparatus (film forming apparatus) according to a first embodiment.

FIG. 2 is a time chart indicating supply of gas in a preparation process and a film forming process performed in the first embodiment.

FIG. 3 is a diagram illustrating a surface of a tungsten nitride film which is formed after a preparation process using WF₆ according to the first embodiment.

FIG. 4 is a diagram illustrating a surface of a tungsten nitride film which is formed without performing a preparation process.

FIG. 5 is a cross section illustrating a structure of a capacitor which employs a tungsten nitride film which is formed in the first embodiment.

FIG. 6 is a diagram illustrating a surface of a tungsten nitride film which is formed by using a halogen element in a preparation process.

FIG. 7 is a diagram illustrating a structure of a manufacturing apparatus which is used in a third embodiment.

FIG. 8 is a diagram illustrating a surface of a tungsten nitride film which is formed by using alcohol in a preparation process.

FIG. 9 is a diagram illustrating a structure of a manufacturing apparatus which is used in a fourth embodiment.

FIG. 10 is a diagram illustrating a surface of a tungsten nitride film which is formed by using HMDS in a preparation process.

FIG. 11 is a diagram illustrating another structure of a manufacturing apparatus which is used in a case where a halogen element is used in a preparation process.

### BEST MODE FOR CARRYING OUT THE INVENTION

### First Embodiment

A first embodiment of the present invention will now be explained with reference to the drawings.

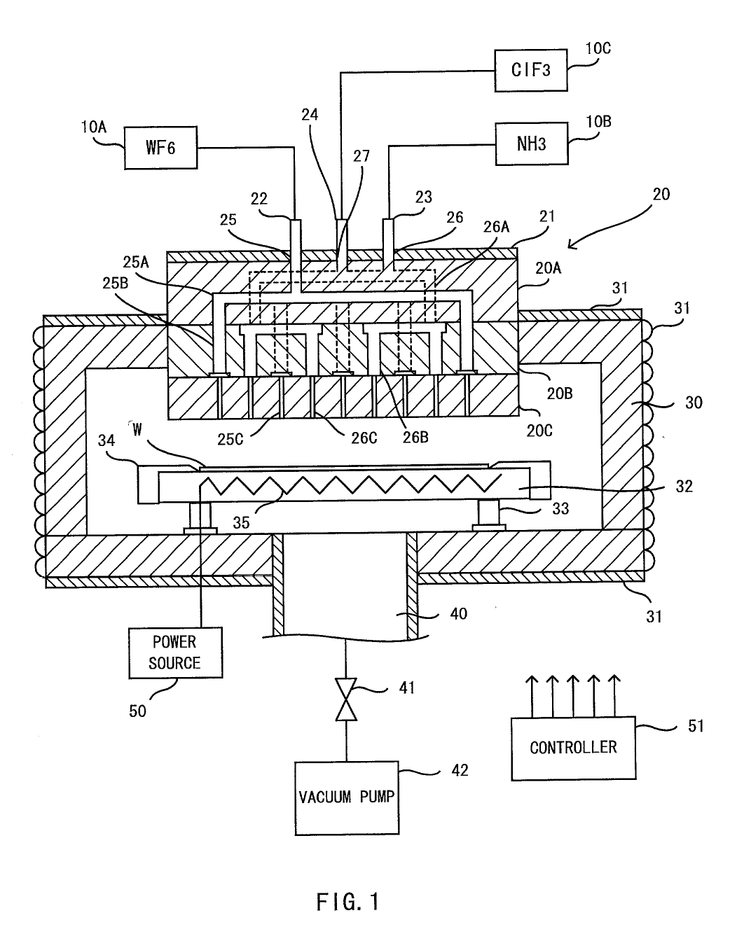

FIG. 1 is a block diagram showing a thermal CVD (Chemical Vapor Deposition) film forming apparatus (hereinafter, referred to as “film forming apparatus) according to the first embodiment. The film forming apparatus shown in FIG. 1 forms a film which is used as a lower electrode included in a capacitor of a semiconductor device.

As shown in FIG. 1, the film forming apparatus according to the first embodiment comprises gas supply sources 10A, 10B, and 10C, a shower head 20, a shower head heater 21, a chamber 30, a chamber heater 31, a susceptor 32, supporting members 33, an exhaust pipe 40, a bulb 41, a vacuum pump 42, a power source 50, and a controller 51.

The gas supply sources 10A, 10B, and 10C supply gases into the chamber 30 via the shower head 20. The gas supply sources 10A and 10B respectively supply gases for applying predetermined processes (a preparation process, a film forming process, etc. to be described later) to a semiconductor wafer W in the chamber 30. The gas supply source 10C supplies a cleaning gas for removing reaction by-products, residual gases, and the like in the chamber 30, after predetermined processes are applied to the semiconductor wafer W. Specifically, the gas supply source 10A supplies WF₆ which is a preparation process gas and also a film forming gas, for example. The gas supply source 10B supplies NH₃ which is a film forming gas, for example. The gas supply source 10C supplies ClF₃ which is a cleaning gas, for example.

The shower head 20 is placed so as to penetrate into the center of the upper wall of the chamber 30, as shown in FIG. 1. The shower head 20 comprises three stages of integrated blocks 20A, 20B, and 20C.

The upper block 20A comprises pipes 22, 23, and 24 on the upper surface thereof which are respectively connected to the gas supply sources 10A, 10B, and 10C. Gas flow ports 25, 26, and 27 which are respectively connected to the pipes 22, 23, and 24 are formed in the upper block 20A.

The gas flow ports 25 and 26 are respectively connected to a first branch gas flow path 25A and a second branch gas flow path 26A each of which branches out in the upper block 20A. The gas flow port 27 is connected to the second branch gas flow path 26A in the upper block 20A. The first branch gas flow path 25A and the second branch gas flow path 26A have openings in the lower surface of the upper block 20A.

In the middle block 20B, first middle block gas flow paths 25B and second middle block gas flow paths 26B are formed which respectively communicate with the first branch gas flow path 25A and the second branch gas flow path 26A. The first middle block gas flow paths 25B and the second middle block gas flow paths 26B respectively penetrate through the middle block 20B, and have openings in the lower surface of the middle block 20B.

In the lower block 20C, first lower block gas flow paths 25C and second lower block gas flow paths 26C are formed which respectively communicate with the first middle block gas flow paths 25B and the second middle block gas flow paths 26B. The first lower block gas flow paths 25C and the second lower block gas flow paths 26C respectively penetrate through the lower block 20C, and have openings in the lower surface of the lower block 20C. The openings are arranged in the lower surface of the lower block 20c at regular intervals.

Via the plurality of gas flow paths which are formed as described above, WF₆ gas and NH₃ gas are supplied from the gas supply sources 10A and 10B to the chamber 30 almost uniformly. As described above, the gas flow paths are prepared for WF₆ gas and NH₃ respectively. Thus, the gases are prevented from reacting with each other in the shower head 20. That is, the gases supplied from the gas supply sources 10A and 10B respectively are mixed with each other only after the gases flow into the chamber 30.

Though not show in FIG. 1, the shower head 20 comprises a gas flow port (gas flow paths) for supplying an inert gas (such as Ar gas, nitrogen gas, etc.) for diluting the preparation process gas and the film forming gas into the chamber 30.

The shower head heater 21 is placed on the upper surface of the shower head 20 to control the temperature in the shower head 20. Temperatures for the preparation process gas, the film forming gas, the cleaning gas, and the dilution gas which flow through the shower head 20 are set at respective predetermined degrees by the shower head heater 21.

The chamber 30 is a process room in which predetermined processes are applied to the semiconductor wafer W.

The chamber heater 31 is arranged on the external walls of the chamber 30 so as to surround the chamber 30, and sets the temperature in the chamber 30 at a predetermined degree.

The susceptor 32 is provided inside the chamber 30. The process target semiconductor wafer W which is transported into the chamber 30 by a transportation mechanism (not illustrated) is placed on the susceptor 32. The susceptor 32 comprises a guide ring 34 at the edge thereof that guides the semiconductor wafer W to the center thereof. The susceptor 32 comprises a stage heater 35 for controlling the temperature of the semiconductor wafer W inside the susceptor 32.

The supporting members 33 are arranged inside the chamber 30 to fix and support the susceptor 32.

The exhaust pipe 40 is provided at the bottom portion of the chamber 30 in order to evacuate gases inside the chamber 30.

The vacuum pump 42 is connected to the exhaust pipe 40 via the bulb 41 which adjusts the amount of gas flow. A reaction by-product capturing trap (not illustrated) for capturing reaction by-products which are produced in the chamber 30 is provided between the vacuum pump 42 and the exhaust pipe 40. The pressure in the chamber 30 can be appropriately adjusted by adjusting the bulb 41.

The power source 50 supplies a voltage to the stage heater 35.

The controller 51 controls each of the above-described members constituting the film forming apparatus in accordance with data previously provided via a recording medium, a network, or the like.

A method of manufacturing a semiconductor device which employs the film forming apparatus shown in FIG. 1 will now be explained. Operations of the respective members of the film forming apparatus to be explained below are controlled by the controller 51.

First, the process target semiconductor wafer W is placed on the susceptor 32 by a transportation mechanism (not illustrated). The power source 50 previously supplies a voltage to the stage heater 35. Thus, the susceptor 32 is set at a predetermined temperature (for example, 450° C.). Therefore, the temperature of the semiconductor wafer W placed on the suscepor 32 is set at 450° C.

The shower head heater 21 and the chamber heater 31 respectively set the shower head 20 and the chamber 30 at a predetermined temperature (for example, 130° C.). Therefore, the preparation process gas and film forming gas flowing through the shower head 20, and internal walls of the chamber 30 (including the shower head 20) are kept at a predetermined temperature (for example, 130° C.).

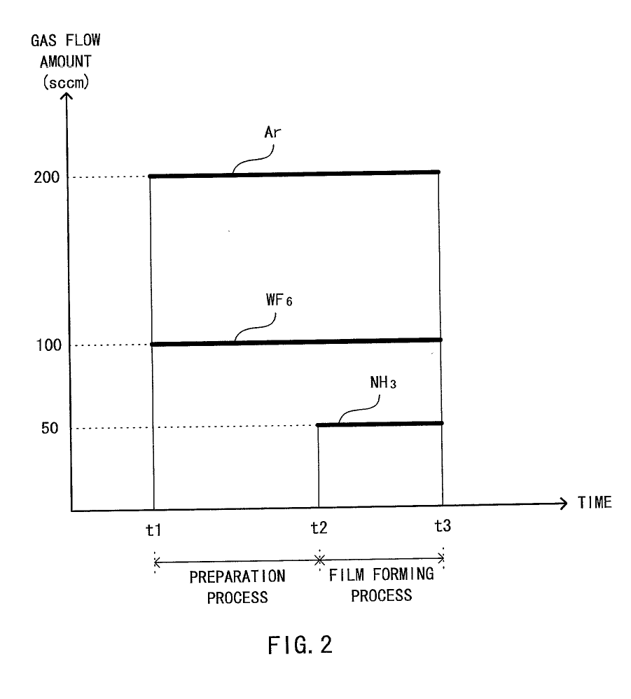

After the respective parts are set at their appropriate temperatures, gases are supplied in accordance with a time chart shown in FIG. 2 to start the preparation process and the film forming process.

In the preparation process, WF₆ gas as the preparation process gas is supplied in a flow amount of 100 (sccm) from the gas supply source 10A via the shower head 20 onto the surface of the semiconductor wafer W (t1). Ar gas for diluting the preparation process gas is supplied in a flow amount of 200 (sccm) via the shower head 20 to the chamber 30 (t1).

After the above preparation process is carried out for 30 seconds, that is, when 30 seconds passes after supply of the preparation process gas is started (t2), the film forming process is successively started.

In the film forming process, NH₃ gas as the film forming gas is supplied from the gas supply source 10B to the chamber 30. During the supply of NH₃, WF₆ gas supplied as the preparation process gas is supplied from the gas supply source 10A to the chamber 30 continuously from the preparation process. Ar gas is also continuously supplied to the chamber 30. Specifically, those gases WF₆, NH₃, and Ar are supplied in the respective flow amounts 100, 50, and 200 (sccm) for 27 seconds (t2 to t3).

After the preparation process and film forming process are carried out in the way described above, a tungsten nitride film whose surface has a bumpy shape can be formed on the semiconductor wafer W.

The semiconductor wafer W on which the tungsten nitride film is formed is transported out from the chamber 30 by the transportation mechanism (not illustrated).

The preparation process and film forming process are applied to a predetermined number of semiconductor wafers W in the same way as described above.

Thereafter, in order to clean the chamber 30, the stage heater 35, the shower head heater 21, and the chamber heater 31 are set at predetermined temperatures respectively, for example, 300° C., 130° C., and 130° C. Then, the cleaning gas (ClF₃ gas) is supplied from the gas supply source 10C to the chamber 30. The pressure in the chamber 30 is kept at a predetermined level, for example, 1 Torr by adjusting thhe bulb 41. Thus, tungsten nitride films deposited on surfaces of the stage heater 35, the shower head 20, and the guide ring 34 are removed.

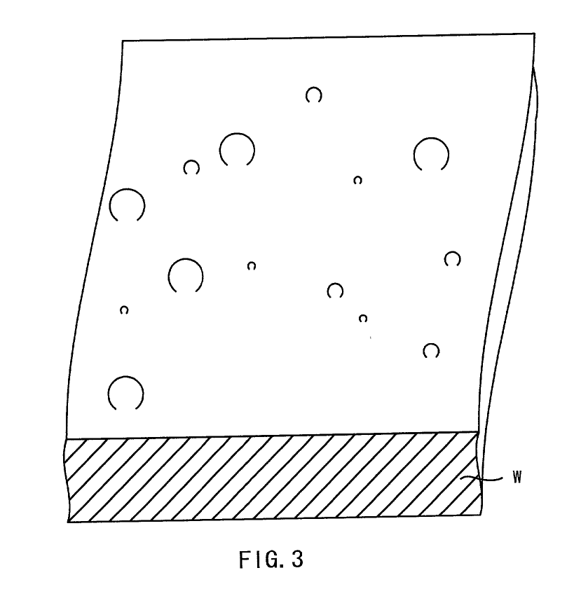

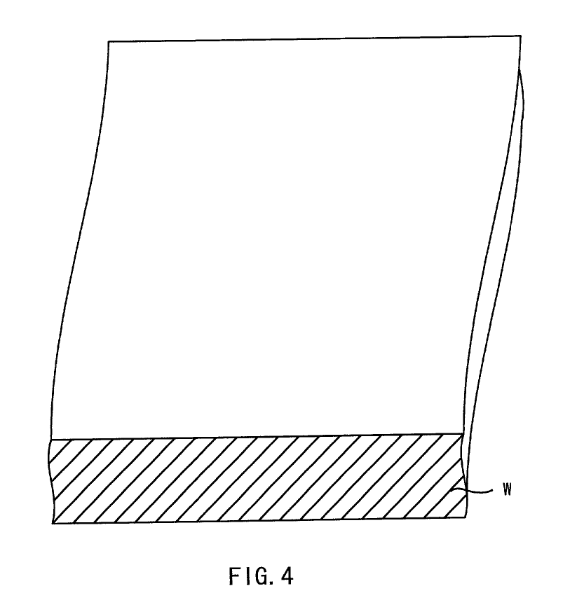

FIG. 3 shows a schematic diagram illustrating the surface of the tungsten nitride film formed as described above. FIG. 4 shows a schematic diagram illustrating the surface of a tungsten nitride film which is formed by a commonly known method. According to a commonly known method, a tungsten nitride film is formed on a semiconductor wafer W by supplying NH₃ gas and after this, supplying WF₆ gas without performing a preparation process such as the above described one.

As shown in FIG. 3, bumps are formed on the surface of the tungsten nitride film which is formed with a preparation process employing WF₆ gas. On the other hand, as shown in FIG. 4, the surface of the tungsten nitride film which is formed without a preparation process is flat.

The surfaces of the tungsten nitride films as shown in FIG. 3 and FIG. 4 were actually able to be observed by an SEM (Scanning Electron Microscope).

The followings are suggested by those results. By supplying WF₆ onto the surface of a semiconductor wafer W before a tungsten nitride film is formed, formation of a tungsten nitride film can be controlled. That is, the density of nuclei (growth nuclei) which are formed during earliest stages of film formation can be reduced. It can be considered that this is because WF₆ is deposited on the surface of the semiconductor wafer W in the preparation process, and the deposited WF₆ restricts (or prevents) formation of nuclei. That is, WF₆ prevents NH₃ which is the other material gas for forming a tungsten nitride film from being adhered onto the semiconductor wafer W.

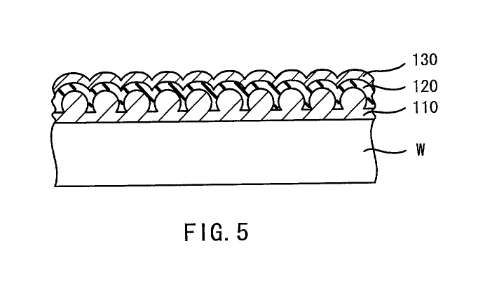

It is possible to manufacture a capacitor having large capacitance by forming bumps on the surface of a tungsten nitride film which will become a lower electrode of the capacitor, as described above. Such a capacitor will be structured as shown in FIG. 5, for example. The capacitor shown in FIG. 5 comprises a semiconductor wafer W, a tungsten nitride film 110 having a bumpy shape and formed on the semiconductor wafer W, a capacitance insulation film 120 formed on the tungsten nitride film 110, and a metal film (or a metal compound film) 130 formed on the capacitance insulation film 120. Although not shown, an interlayer insulation film made of SiO₂, Si₃N₄, BPSG, or the like, and a titanium nitride film are sequentially formed between the semiconductor wafer W and the tungsten nitride film 110. A titanium nitride film may not be formed.

Being combined with a transistor, a capacitor as a trench structure including a lower electrode made of a tungsten nitride film having a bumpy shape can form a memory (DRAM) having a large capacity.

Further, since a tungsten nitride film is not easily oxidized, high performance reliability can be ensured for a semiconductor device to be manufactured.

### Second Embodiment

A second embodiment of the present invention will now be explained with reference to the drawings.

A film forming apparatus according to the second embodiment are substantially identical to the film forming apparatus described in the first embodiment. However, the gas supply source 10C supplies ClF₃ gas which is a halogen gas to the chamber 30 as a preparation process gas and a cleaning gas.

A method of manufacturing a semiconductor device according to a second embodiment will be explained below. Operations of the respective members of the film forming apparatus to be explained below are controlled by the controller 51 mentioned above.

A process target semiconductor wafer W is placed on the susceptor 32 by a transportation mechanism (not shown). The susceptor 32 is previously set at a temperature of 150° C. with supply of a voltage to the stage heater 35 from the power source 50. Thus, the temperature of the semiconductor wafer W placed on the susceptor 32 is set at 150° C.

The gas supply source 10C supplies ClF₃ gas which is the preparation process gas to the chamber 30 via the shower head 20. At this time, by adjusting the bulb 41, the pressure inside the chamber 30 is adjusted so that the partial pressure of ClF₃ becomes 50 mTorr.

The preparation process is performed with the supply of the ClF₃ gas onto the surface of the semiconductor wafer W for 30 seconds in the way described above.

After the preparation process is applied to the semiconductor wafer W, the power source 50 sets the stage heater 35 at a temperature of 300 to 600° C. (specifically, 450° C., for example). Thus, the temperature of the semiconductor wafer W is set at 450° C.

The shower head heater 21 and the chamber heater 31 respectively set the shower head 20 and the chamber 30 at a predetermined temperature (for example, 130° C.). Thus, a gas flowing through the shower head 20 and internal walls of the chamber 30 are kept at the predetermined temperature (for example, 130° C.).

Afterwards, the gas supply sources 10A and 10B supply WF₆ gas and NH₃ gas which are the film forming gases to the chamber 30 through the shower head 20 in a film forming process to be described below. Ar gas (dilution gas) for diluting material gases is supplied to the chamber 30 via the shower head 20, if necessary.

The film forming process includes a first step an a second step.

In the first step, the pressure inside the chamber 30 is set at 1 Torr. Then, the film forming gases WF₆ and NH₃, and the dilution gas Ar are supplied in 0, 50, and 200 (sccm) respectively for 30 seconds.

In the second step, the pressure inside the chamber 30 is set at 1 Torr. Then, the film forming gases WF₆ and NH₃, and the dilution gas Ar are supplied in 100, 50, and 200 (sccm) respectively for 27 seconds.

By performing film formation in accordance with this film forming process, a tungsten nitride film can be formed on the semiconductor wafer W which has been subjected to the preparation process.

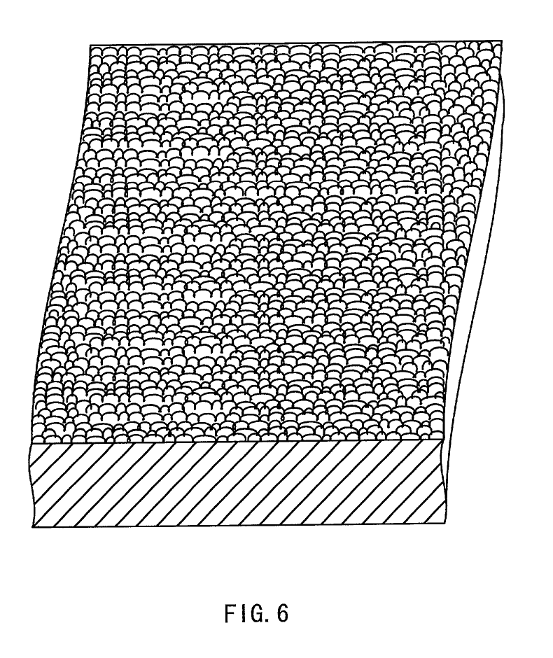

FIG. 6 shows a schematic diagram illustrating the surface of the tungsten nitride film which is formed in the way described above.

As shown in FIG. 6, numerous small bumps are formed on the surface of the tungsten nitride film which is formed after the preparation process using ClF₃ gas is performed. Such a surface of the tungsten nitride film as having many small bumps was actually able to be observed by an SEM (Scanning Electron Microscope).

From this result, it is considered that a gas including ClF₃ gas (halogen element) has a material characteristic that it is likely to be adhered to the surface of a semiconductor wafer W, and NH₃ is prevented from being adhered to the semiconductor wafer W by supplying the halogen element onto the surface of the semiconductor wafer W before formation of a tungsten nitride film. As a result, the density of nuclei (growth nuclei) which are formed during early stages of film formation is reduced, and thus, the surface of the tungsten nitride film becomes bumpy.

As described above, by forming bumps on the surface of a tungsten nitride film to be a lower electrode of a capacitor, a capacitor having large capacitance can be manufactured. Such a capacitor may be structured as shown in FIG. 5, for example. This capacitor, if combined with a transistor, can form a memory having a large capacity.

Further, since a tungsten nitride film is not easily oxidized, high performance reliability can be ensured for a semiconductor device to be manufactured.

### Third Embodiment

A third embodiment of the present invention will now be explained with reference to the drawings.

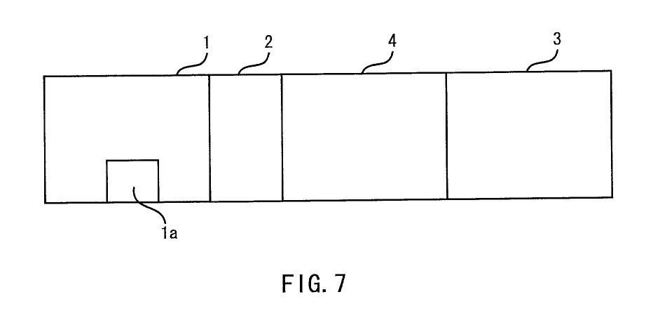

In a manufacturing method according to the third embodiment, C₂H₅OH (alcohol) is coated on a semiconductor wafer W, and then the semiconductor wafer is dried in a preparation process. The preparation process including this coating step can be simplified with the use of a manufacturing apparatus shown in FIG. 7, for example.

The manufacturing apparatus shown in FIG. 7 comprises a preparation process room 1, a transportation mechanism 2, a film forming apparatus 3, and a load lock room 4.

The preparation process room 1 comprises a spin coater 1a which coats a semiconductor wafer W with C₂H₅OH.

The transportation mechanism 2 comprises a transportation arm or the like for transporting the semiconductor wafer W between the preparation process room 1 and the film forming apparatus 3.

The film forming apparatus 3 is substantially identical to the film forming apparatus described in the first or second embodiment, and forms a tungsten nitride film on the semiconductor wafer W to which the preparation process is applied in the preparation process room 1.

The load lock 4 is provided so that the semiconductor wafer W is transported while the pressure inside the film forming apparatus 3 is kept unchanged. That is, the transportation mechanism 2 transports the semiconductor wafer W to the film forming apparatus 3 via the load lock room 4.

A method of manufacturing a semiconductor device employing the manufacturing apparatus shown in FIG. 7 will now be explained.

First, the preparation process is applied to the semiconductor wafer W in the preparation process room 1. Specifically, the spinning coater 1 spin-coats C₂H₅OH on the surface of the semiconductor wafer W, and dries C₂H₅OH. Since C₂H₅OH is alcohol, the preparation process can be performed at a normal temperature under an atmospheric pressure.

After the preparation process is applied to the semiconductor wafer W, the transportation mechanism 2 transports the semiconductor wafer W into the film forming apparatus 3 via the load lock 4.

In the film forming apparatus 3, a tungsten nitride film is formed on the semiconductor wafer W in the film forming process described in the second embodiment.

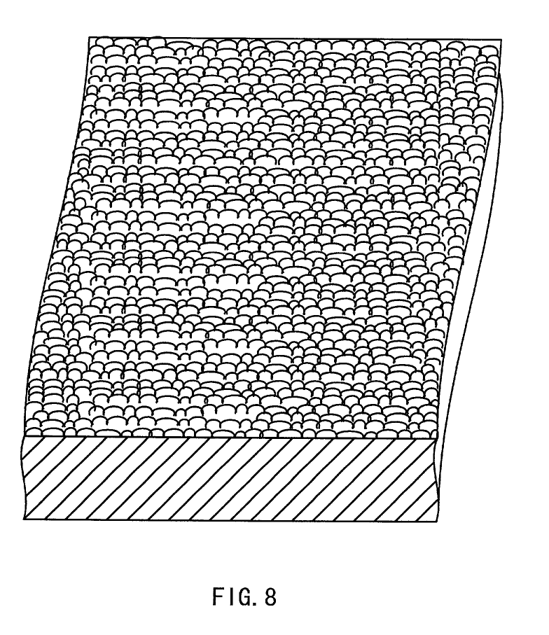

FIG. 8 shows a schematic diagram illustrating the surface of the tungsten nitride film which is formed in the way described above.

As shown in FIG. 8, numerous bumps which are relatively larger than those formed in case of the second embodiment (FIG. 6) are formed on the surface of the tungsten nitride film which is formed after the preparation process using C₂H₅OH is carried out. Such a surface of the tungsten nitride film was actually able to be observed by an SEM (Scanning Electron Microscope).

From this result, it is considered that since an organic solvent having a polarity such as alcohol is likely to be adhered to the semiconductor wafer W, NH₃ is prevented from being adhered to the semiconductor wafer W by coating alcohol to the surface of the semiconductor wafer W before formation of the tungsten nitride film. As a result, the density of nuclei (growth nuclei) which are formed during early stages of film formation is considered to be reduced.

As described above, by forming bumps on the surface of the tungsten nitride film which will be a lower electrode of a capacitor, a capacitor having large capacitance can be manufactured. Such a capacitor may be structured as shown in FIG. 5, for example. Such a capacitor, if combined with a transistor, can form a memory having a large capacity.

Further, since the tungsten nitride film is not easily oxidized, high performance reliability can be ensured for a semiconductor device to be manufactured.

Since alcohol is employed in the preparation process, the structure of an apparatus necessary for the preparation process can be simplified. Thus, the cost of the apparatus can be saved.

### Fourth Embodiment

A fourth embodiment will now be explained with reference to the drawings.

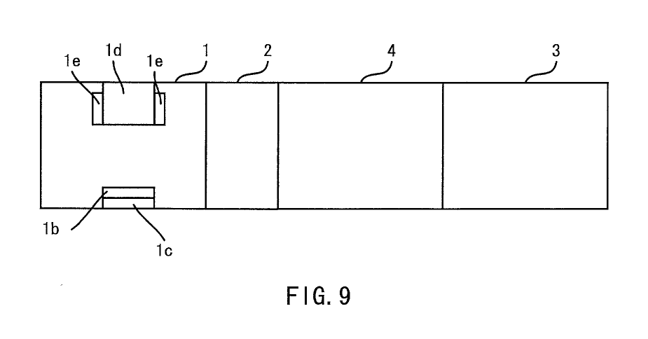

In a manufacturing method according to the fourth embodiment, the preparation process is carried out with the use of HMDS. Specifically, a semiconductor wafer W is exposed to the vapor of HMDS, and then dried. Since this preparation process is performed under an atmospheric pressure, the preparation process and the film forming process can be performed by a manufacturing apparatus shown in FIG. 9.

The manufacturing apparatus shown in FIG. 9 comprises a preparation process room 1, a transportation mechanism 2, a film forming apparatus 3, and a load lock room 4.

The preparation process room 1 comprises a stage 1b on which the semiconductor wafer W is to be placed, a stage heater 1c, a vapor supply source 1d which erupts vapor of HMDS, and a vapor heater 1e. The stage heater 1c sets the semiconductor wafer W at a predetermined temperature by heating the stage 1b. The vapor heater 1e sets the vapor of HMDS at a predetermined temperature by heating the vapor supply source 1d.

The transportation mechanism 2 comprises a transportation arm or the like, which transports the semiconductor wafer W between the preparation process room 1 and the film forming apparatus 3.

The film forming apparatus 3 is substantially identical to the film forming apparatus described in the first or second embodiment, and forms a tungsten nitride film on the semiconductor wafer W to which the preparation process has been applied.

The load lock room 4 is provided so that the semiconductor wafer W is transported while the pressure inside the film forming apparatus 3 is kept unchanged. That is, the transportation mechanism 2 transports the semiconductor wafer W to the film forming apparatus 3 via the load lock room 4.

A method of manufacturing a semiconductor device employing the manufacturing apparatus shown in FIG. 9 will be explained.

The temperature of the stage 1b is set at 25° C. by heating the stage 1b with the use of the stage heater 1c of the preparation process room 1.

The vapor heater 1e heats the vapor supply source 1d so that the temperature of the vapor of HMDS reaches 25° C.

Thereafter, a process target semiconductor wafer W is placed on the stage 1b of the preparation process room 1, and the temperature of the semiconductor wafer W is set at 25° C.

When the temperature of the semiconductor wafer W reaches the predetermined temperature, the vapor supply source Id supplies vapor of HMDS which is heated to 25° C. onto the surface of the semiconductor wafer W.

After the preparation process described above is performed under an atmospheric pressure for 120 seconds, the transportation mechanism 2 transports the semiconductor wafer W into the film forming apparatus 3 via the load lock room 4.

In the film forming apparatus 3, a tungsten nitride film is formed on the semiconductor wafer W in the film forming process described in the second embodiment.

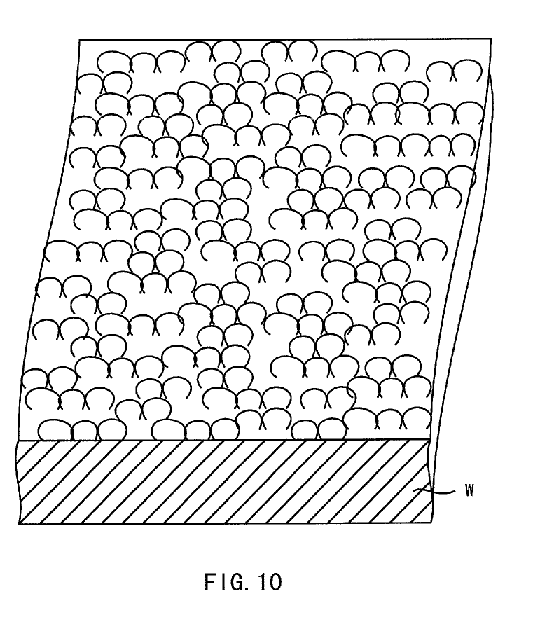

FIG. 10 shows a schematic diagram illustrating the surface of the tungsten nitride film which is formed in the above described way.

As shown in FIG. 10, numerous large bumps are formed on the surface of the tungsten nitride film which is formed after the preparation process using the vapor of HMDS is performed. Such a surface of the tungsten nitride film was actually able to be observed by an SEM (Scanning Electron Microscope).

From the above result, it is considered that —H included in —OH groups which exist in the surface of the semiconductor wafer W is substituted by —Si(CH₃)₃ by exposing the surface of the semiconductor wafer W to the vapor of HMDS, and thus formed —O—Si(CH₃)₃ groups in the surface of the semiconductor wafer W prevents NH₃ from being adhered to the semiconductor wafer W. As a result, the density of nuclei (growth nuclei) which are formed during early stages of tungsten nitride film formation is considered to be reduced.

As described above, by forming bumps on the surface of the tungsten nitride film which will become a lower electrode of a capacitor, a capacitor having large capacitance can be manufactured. Such a capacitor may be structured as shown in FIG. 5. Such a capacitor, if combined with a transistor, cam form a memory having a large capacity.

Further, since the tungsten nitride film is not easily oxidized, high performance reliability can be ensured for a semiconductor device to be manufactured.

Since the preparation process is performed under an atmospheric pressure, a device such as a vacuum pump is not necessary for performing the preparation process. Thus, the costs of devices can be saved.

As described in the first to fourth embodiments, if materials to be used in the preparation process are changed, size and number of bumps to be formed on the surface of the tungsten nitride film are varied. Thus, it is possible to choose materials to be used in the preparation process differently in accordance with usage purposes of capacitors to be manufactured. Also, size and number of bumps can be controlled by changing time in which the preparation process is applied.

In the second embodiment, it is possible to form bumps on the surface of the tungsten nitride film even if the conditions for the preparation process are changed (temperature of the semiconductor wafer W: 300° C., partial pressure of ClF₃: 10 mTorr, time for flowing ClF₃: 30 seconds).

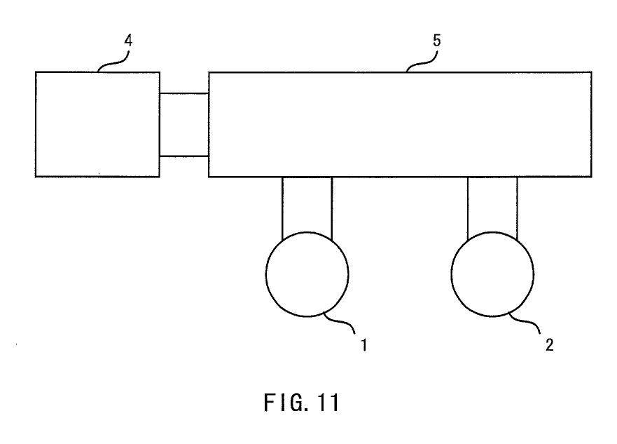

Further, in case of using a halogen element (WF₆, ClF₃, and the like) in the preparation process, it is possible to form a tungsten nitride film using a manufacturing apparatus shown in FIG. 11. In the manufacturing apparatus shown in FIG. 11, the preparation process room 1 and the film forming apparatus 3 are connected to each other via a vacuum transportation room 5. The load lock room 4 is connected to the vacuum transportation room 5 so that a semiconductor wafer W can be transported while the pressure inside the vacuum transportation room 5 is kept unchanged. By connecting the preparation process room 1 and the film forming apparatus 3 via the vacuum transportation room 5, oxidization of the semiconductor wafer W, adhesion of water, detachment of objects formed on the semiconductor wafer, and the like can be prevented.

In the third and fourth embodiments, a case where the preparation process room 1 and the film forming apparatus 3 are prepared separately is exemplified. However, the preparation process room 1 and the film forming apparatus 3 may be a same process room.

In the preparation process described in the third embodiment, the same effect as described above can be obtained if HMDS, or ketone such as acetone, is coated and dried instead of alcohol.

In the preparation process described in the fourth embodiment, the surface of the semiconductor wafer W may be exposed to the vapor of alcohol or ketone and then dried instead of HMDS. The same effect as described above can also be obtained by this change.

### INDUSTRIAL APPLICABILITY

As described above, a semiconductor device including a capacitor having large capacitance can be obtained by employing the present invention. And, a semiconductor device including a metal film having a bumpy shape can be obtained.

The present U.S. Patent Application is based on Japanese Patent Application No. H11-210149 (filed on Jul. 26, 1999) and International Patent Application No. PCT/JP00/04889 (filed on Jul. 21, 2000). The contents of those patent applications are incorporated herein by reference in their entireties.

1. A method of manufacturing a semiconductor device comprising:
a preparation process step of supplying a substance for restricting formation of nuclei for growing a metal film or a metal compound film onto a surface of a process target substrate; and
a film forming step of forming a metal film or a metal compound film whose surface has bumps on said substrate by supplying a material of said metal film or said metal compound film onto the surface of said substrate after said preparation process step.

2. The method of manufacturing a semiconductor device according to claim 1, wherein:
said preparation process step comprises a step of supplying a substance for restricting adhesion of NH₃ onto the surface of said substrate; and
said film forming step comprises a step of forming a tungsten nitride film whose surface has bumps on said substrate by supplying WF₆ and NH₃ onto the surface of said substrate.

3. The method of manufacturing a semiconductor device according to claim 2, wherein
said preparation process step comprises a step of restricting adhesion of NH₃ onto the surface of said substrate by supplying a halogen element onto the surface of said substrate.

4. The method of manufacturing a semiconductor device according to claim 3, wherein
said preparation process step comprises a step of supplying ClF₃ or WF₆ onto the surface of said substrate as said halogen element.

5. The method of manufacturing a semiconductor device according to claim 2, wherein
said preparation process step comprises a step of restricting adhesion of NH₃ onto the surface of said substrate by bonding groups made of C and H onto the surface of said substrate.

6. The method of manufacturing a semiconductor device according to claim 5, wherein
said preparation process step comprises a step of coating at least one of HMDS ((CH₃)₃SiNHSi(CH₃)₃), alcohol, and ketone onto the surface of said substrate in order to bond groups made of C and H onto the surface of said substrate.

7. The method of manufacturing a semiconductor device according to claim 5, wherein
said preparation process step comprises a step of exposing the surface of said substrate to vapor of at least one of HMDS, alcohol, and ketone in order to bond groups made of C and H onto the surface of said substrate.

8. The method of manufacturing a semiconductor device according to claim 6, wherein
said preparation process step comprises a step of using C₂H₅OH as the alcohol.

9. The method of manufacturing a semiconductor device according to claim 7, wherein
said preparation process step comprises a step of using C₂H₅OH as the alcohol.

10. The method of manufacturing a semiconductor device according to claim 6, wherein
said preparation process step comprises a step of using CH₃COCH₃ as the ketone.

11. The method of manufacturing a semiconductor device according to claim 7, wherein
said preparation process step comprises a step of using CH₃COCH₃ as the ketone.

12. A method of manufacturing a semiconductor device comprising:
a preparation process step of supplying a halogen element onto a surface of a substrate; and
a film forming step of forming a metal film or a metal compound film whose surface has bumps on said substrate by supplying a material of said metal film or said metal compound film onto the surface of said substrate after said preparation process step.

13. A method of manufacturing a semiconductor device comprising:
a preparation process step of bonding groups made of C and H onto a surface of a substrate; and
a film forming step of forming a metal film or a metal compound film whose surface has bumps on said substrate by supplying a material of said metal film or said metal compound film onto the surface of said substrate after said preparation process step.

14. The method of manufacturing a semiconductor device according to claim 1, wherein
said film forming step controls a shape of the bumps on said metal film or said metal compound film formed in said film forming step by controlling a time in which a preparation process is performed.

15. The method of manufacturing a semiconductor device according to claim 12, wherein
said film forming step controls a shape of the bumps on said metal film or said metal compound film formed in said film forming step by controlling a time in which a preparation process is performed.

16. The method of manufacturing a semiconductor device according to claim 13, wherein
said film forming step controls a shape of the bumps on said metal film or said metal compound film formed in said film forming step by controlling a time in which a preparation process is performed.

17. An apparatus for manufacturing a semiconductor device comprising:
a first process room in which a preparation process is applied to a substrate;
a restriction substance supply source which supplies a restriction substance for restricting formation of nuclei for growing a metal film or a metal compound film to said first process room;
a second process room in which a film forming process for forming a metal film or a metal compound film whose surface has bumps is performed; and
a material gas supply source which supplies a material gas for forming said metal film or said metal compound film whose surface has bumps to said second process room.

18. The apparatus for manufacturing a semiconductor device according to claim 17, wherein:
said restriction substance supply source supplies onto a surface of said substrate which is arranged on a predetermined position in said first process room, a gas including a halogen element for restricting adhesion of NH₃ as the preparation process; and
said material gas supply source forms a tungsten nitride film on said substrate by supplying WF₆ gas and NH₃ gas onto the surface of said substrate to which the preparation process has been applied.

19. The apparatus for manufacturing a semiconductor device according to claim 18, wherein
said restriction substance supply source supplies WF₆ or ClF₃ as the halogen element.

20. The apparatus for manufacturing a semiconductor device according to claim 18, wherein
said restriction substance supply source includes gas guiding means for supplying the gas including a halogen element onto said substrate substantially uniformly.

21. The apparatus for manufacturing a semiconductor device according to claim 17, wherein
said first process room and said second process room are capable of keeping a pressure therein at a predetermined level, and are connected to each other via a vacuum room which includes transportation means for transporting said substrate.

22. The apparatus for manufacturing a semiconductor device according to claim 17, wherein
said first process room and said second process room are a same process room.

23. The apparatus for manufacturing a semiconductor device according to claim 18, wherein
said material gas supply source supplies WF₆ gas and NH₃ gas onto said substrate in said second process room via different paths respectively.

24. The apparatus for manufacturing a semiconductor device according to claim 17, wherein:
said restriction substance supply source supplies a substance including groups made of C and H as the restriction substance as the preparation process; and
said first process room includes coat and dry means for bonding groups made of C and H onto a surface of said substrate by coating and drying the restriction substance on the surface of said substrate.

25. The apparatus for manufacturing a semiconductor device according to claim 17, wherein:
said restriction substance supply source supplies a substance including groups made of C and H as the restriction substance as the preparation process; and
said first process room includes means for bonding groups made of C and H onto a surface of said substrate by flowing vapor of the restriction substance above the surface of said substrate.

26. The method of manufacturing a semiconductor device according to claim 1, wherein:
said preparation process step is a step of supplying the substance for restricting formation of nuclei onto the surface of said substrate that is substantially plane; and
said film forming step is a step of forming a metal film or a metal compound film which has bumps on said substrate.

27. The method of manufacturing a semiconductor device according to claim 1, wherein:
said preparation process step is a step of supplying the substance for restricting formation of nuclei onto the surface of said substrate that has predetermined roughness; and
said film forming step is a step of forming on said substrate, a metal film or a metal compound film which has bumps that are rougher than the surface of said substrate.

28. The method of manufacturing a semiconductor device according to claim 1, further comprising
a step of forming a conductive film which faces said metal film or said metal compound film via an insulation material,
wherein said method forms capacitance.

29. The method of manufacturing a semiconductor device according to claim 12, wherein:
said preparation process step is a step of supplying the substance for restricting formation of nuclei onto the surface of said substrate that is substantially plane; and
said film forming step is a step of forming a metal film or a metal compound film which has bumps on said substrate.

30. The method of manufacturing a semiconductor device according to claim 12, wherein:
said preparation process step is a step of supplying the substance for restricting formation of nuclei onto the surface of said substrate that has predetermined roughness; and
said film forming step is a step of forming on said substrate, a metal film or a metal compound film which has bumps that are rougher than the surface of said substrate.

31. The method of manufacturing a semiconductor device according to claim 12, further comprising
a step of forming a conductive film which faces said metal film or said metal compound film via an insulation material,
wherein said method forms capacitance.

32. The method of manufacturing a semiconductor device according to claim 13, wherein:
said preparation process step is a step of supplying the substance for restricting formation of nuclei onto the surface of said substrate that is substantially plane; and
said film forming step is a step of forming a metal film or a metal compound film which has bumps on said substrate.

33. The method of manufacturing a semiconductor device according to claim 13, wherein:
said preparation process step is a step of supplying the substance for restricting formation of nuclei onto the surface of said substrate that has predetermined roughness; and
said film forming step is a step of forming on said substrate, a metal film or a metal compound film which has bumps that are rougher than the surface of said substrate.

34. The method of manufacturing a semiconductor device according to claim 13, further comprising
a step of forming a conductive film which faces said metal film or said metal compound film via an insulation material,
wherein said method forms capacitance.

35. The apparatus for manufacturing a semiconductor device according to claim 17, wherein
said second process room forms a metal film or a metal compound film on a surface of said substrate on which formation of nuclei is restricted by the process performed in said first process room, the surface having predetermined roughness and said metal film or said metal compound film having bumps which are rougher than the surface of said substrate.

36. The apparatus for manufacturing a semiconductor device according to claim 17, wherein
said second process room forms a metal film or a metal compound film which has bumps on a surface of said substrate on which formation of nuclei is restricted by the process performed in said first process room, the surface being plane.

37. The apparatus for manufacturing a semiconductor device according to claim 17, further comprising:
a device which forms an insulation material on said metal film or said metal compound film; and
a device which forms a conductive material on said insulation material.
